(19) United States
(12) Patent Application Publication
(10) Pub. No.: US 2026/0122735 A1
(43) Pub. Date: Apr. 30, 2026

(54) SUBSTRATE PROCESSING APPARATUS INCLUDING ANTENNA

(71) Applicant: Samsung Electronics Co., Ltd., Suwon-si (KR)

(72) Inventors: Hyunseok KANG, Suwon-si (KR); Hyeongun JEON, Suwon-si (KR); Yeontae KIM, Suwon-si (KR); Yihwan KIM, Suwon-si (KR); Sunwoo BANG, Suwon-si (KR); Kwanghyun YANG, Suwon-si (KR); Sungyong LIM, Suwon-si (KR); Hyeonjin JEON, Suwon-si (KR)

(73) Assignee: Samsung Electronics Co., Ltd., Suwon-si (KR)

(21) Appl. No.: 19/364,646

(22) Filed: Oct. 21, 2025

(30) Foreign Application Priority Data
Oct. 30, 2024 (KR) 10-2024-0150780

(51) Int. Cl. H05B 6/68; C23C 16/48; H05B 1/02; H05B 6/64; H05B 6/72

(52) U.S. Cl. CPC H05B 6/68; C23C 16/481; H05B 1/0233; H05B 6/6447; H05B 6/72

(57) ABSTRACT

A substrate processing apparatus includes a chamber, a boat inside the chamber, the boat configured to support one or more semiconductor substrates, first and second antennas connected to sidewalls of the chamber, the first and second antennas facing each other, a first signal generator configured to transmit a first microwave signal to the first antenna, a first rod connected to the first antenna, the first rod configured to remove a second microwave signal received by the first antenna, a second rod connected to the second antenna, the second rod configured to remove the first microwave signal received by the second antenna, and processing circuitry configured to control at least the first signal generator.

### CROSS-REFERENCE TO RELATED APPLICATION(S)

This U.S. non-provisional application claims the benefit of priority to Korean Patent Application No. 10-2024-0150780, filed on Oct. 30, 2024 in the Korean Intellectual Property Office, the disclosure of which is incorporated herein by reference in its entirety.

### BACKGROUND

One or more example embodiments of the inventive concepts relate to a substrate processing apparatus including an antenna, a system including a substrate processing apparatus, and/or a method of operating a substrate processing apparatus, etc.

As demand for implementation of high performance, high speed, and/or multifunctionalization of semiconductor devices increases, the degree of integration of semiconductor devices has been increasing. The processes of depositing, etching, and annealing a thin film on a wafer may be performed. In order to improve the productivity of a semiconductor device manufacturing process, it is desired and/or necessary to heat the wafer rapidly and evenly.

### SUMMARY

An aspect of at least one example embodiment of the inventive concepts provides a substrate processing apparatus including an antenna disposed to face a sidewall of a chamber, a system including a substrate processing apparatus, and/or a method of operating a substrate processing apparatus, etc.

According to at least one example embodiment of the inventive concepts, there is provided a substrate processing apparatus including a chamber, a boat inside the chamber, the boat configured to support one or more semiconductor substrates, first and second antennas connected to sidewalls of the chamber, the first and second antennas facing each other, a first signal generator configured to transmit a first microwave signal to the first antenna, a first rod connected to the first antenna, the first rod configured to remove a second microwave signal received by the first antenna, a second rod connected to the second antenna, the second rod configured to remove the first microwave signal which was received by the second antenna, and processing circuitry configured to control at least the first signal generator.

According to at least one example embodiment of the inventive concepts, there is provided a substrate processing apparatus including a chamber, a boat inside the chamber, the boat configured to support one or more semiconductor substrates, first and second antennas connected to sidewalls of the chamber with the one or more semiconductor substrates interposed therebetween, a first signal generator configured to transmit a first microwave signal to the first antenna, a first rod connected to the first antenna, the first rod configured to remove a second microwave signal received by the first antenna, a second rod connected to the second antenna, the second rod configured to remove the first microwave signal received by the second antenna, and processing circuitry configured to control at least the first signal generator. The one or more semiconductor substrates are heated by the first microwave signal.

According to at least one example embodiment of inventive concepts, there is provided a substrate processing apparatus including a chamber, a boat inside the chamber, the boat configured to support one or more semiconductor substrates, a support configured to support the boat, a drive shaft configured to rotate the support and the boat in a horizontal direction, first and second antennas connected to sidewalls of the chamber, the first and second antennas facing each other, a first signal generator configured to transmit a first microwave signal to the first antenna, a first rod connected to the first antenna, the first rod configured to remove a second microwave signal received by the first antenna, a second rod connected to the second antenna, the second rod configured to remove the first microwave signal received by the second antenna, and processing circuitry configured to control at least the first signal generator. Widths of the first antenna and the second antenna increase as distances between the first antenna and the second antenna and the chamber respectively decreases.

According to at least one example embodiment of the inventive concepts, there is provided a method of operating a substrate processing apparatus including transmitting, using at least one first antenna, at least one first microwave signal to at least one semiconductor substrate, the at least one first microwave signal heating the at least one semiconductor substrate, the at least one first antenna on a first wall of a chamber, receiving, using at least one second antenna, the at least one first microwave signal, the at least one second antenna on a second wall of the chamber opposite the first wall of the chamber, and removing, using at least one second rod connected to the at least one second antenna, the at least one first microwave signal from the substrate processing apparatus.

Some example embodiments provide that the method may further include transmitting, using the at least one second antenna, at least one second microwave signal to the at least one semiconductor substrate, the at least one second microwave signal heating the at least one semiconductor substrate, receiving, using the at least one first antenna, the at least one second microwave signal, and removing, using at least one first rod connected to the at least one first antenna, the at least one second microwave signal from the substrate processing apparatus.

Some example embodiments provide that a phase of the at least one first microwave signal may be synchronized with a phase of the at least one second microwave signal such that the at least one first microwave signal and the at least one second microwave signal form a standing wave.

Some example embodiments provide that the at least one second antenna is a plurality of second antennas, the plurality of second antennas arranged in a vertical direction along the second wall of the chamber.

Some example embodiments provide that the at least one first antenna is a directional antenna.

Some example embodiments provide that the at least one second antenna is a directional antenna.

Some example embodiments provide that the method may further include transmitting, using at least one third antenna, at least one third microwave signal to the at least one semiconductor substrate, the at least one third microwave signal heating the at least one semiconductor substrate, the at least one third antenna on a third wall of a chamber, receiving, using at least one fourth antenna, the at least one third microwave signal, the at least one fourth antenna on a fourth wall of the chamber opposite the third wall of the chamber, and removing, using at least one fourth rod connected to the at least one fourth antenna, the at least one third microwave signal from the substrate processing apparatus.

Some example embodiments provide that the method may further include transmitting, using the at least one fourth antenna, at least one fourth microwave signal to the at least one semiconductor substrate, the at least one fourth microwave signal heating the at least one semiconductor substrate, receiving, using the at least one third antenna, the at least one fourth microwave signal, and removing, using at least one third rod connected to the at least one third antenna, the at least one fourth microwave signal from the substrate processing apparatus.

Some example embodiments provide that the at least one third antenna is a plurality of third antennas, the plurality of third antennas arranged in a vertical direction along the third wall of the chamber.

Some example embodiments provide that the at least one fourth antenna is a plurality of fourth antennas, the plurality of fourth antennas arranged in a vertical direction along the fourth wall of the chamber.

### BRIEF DESCRIPTION OF DRAWINGS

The above and other aspects, features, and advantages of one or more example embodiments of the inventive concepts will be more clearly understood from the following detailed description, taken in conjunction with the accompanying drawings, in which:

FIG. 1 is a cross-sectional view of a substrate processing apparatus according to at least one example embodiment;

FIG. 2 is a plan view of the substrate processing apparatus illustrated in FIG. 1;

FIG. 3 is a perspective view of an antenna according to at least one example embodiment;

FIGS. 4A to 4C are perspective views of an antenna according to at least one example embodiment;

FIG. 5 is a schematic diagram illustrating a microwave being transmitted from an antenna according to a comparative example embodiment and at least one example embodiment;

FIGS. 6 and 7 illustrate a frequency change over time of a microwave according to some example embodiments;

FIGS. 8 and 9 are plan views of a substrate processing apparatus according to some example embodiments; and

FIGS. 10 and 11 are cross-sectional views of a substrate processing apparatus according to some example embodiments.

### DETAILED DESCRIPTION

Hereinafter, some example embodiments of the inventive concepts will be described with reference to the accompanying drawings as follows.

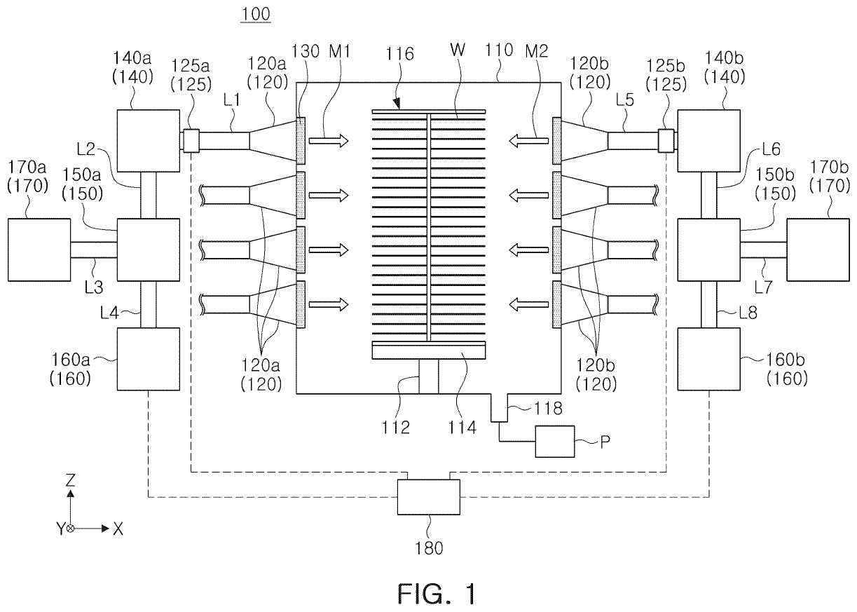

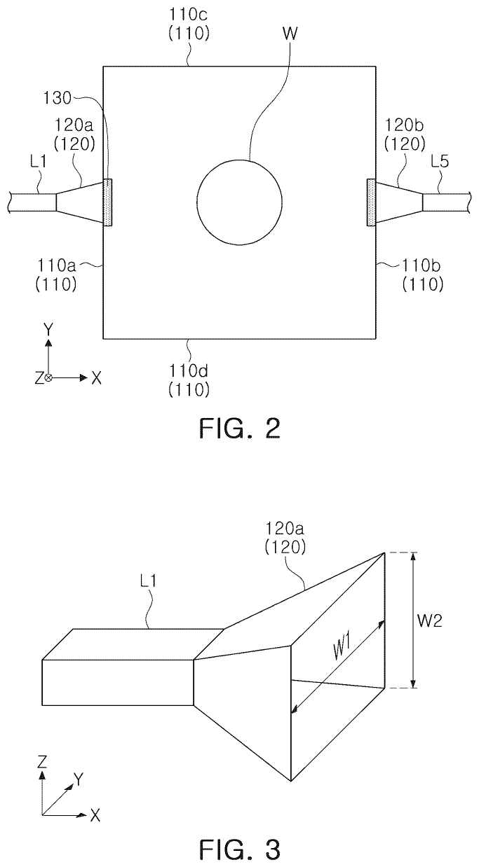

FIG. 1 is a cross-sectional view of a substrate processing apparatus according to at least one example embodiment. FIG. 2 is a plan view of the substrate processing apparatus illustrated in FIG. 1.

Referring to FIGS. 1 and 2, a substrate processing apparatus 100 according to at least one example embodiment may include at least tone chamber 110, a plurality of antennas 120, one or more sensors 125, one or more windows 130, one or more tuners 140, one or more circulators 150, one or more signal generators 160, one or more rods 170, and/or at least one controller 180, etc., but is not limited thereto, and for example, may include a greater or lesser number of constituent components.

In at least one example embodiment, the chamber 110 may be a deposition chamber for growing a thin film on a substrate W (e.g., semiconductor substrate, etc.). For example, the chamber 110 may be a chamber for epitaxial growth and/or selective epitaxial growth (SEG), a low pressure chemical vapor deposition (LPCVD) chamber, and/or a very low pressure chemical vapor deposition (VLPCVD) chamber, etc. However, the chamber 110 is not limited to the above-described chambers.

A heating process may be performed on a plurality of substrates W in the chamber 110. For example, the chamber 110 may be a batch-type chamber, and the substrates W may be vertically stacked and disposed, but is not limited thereto. For example, at least one drive shaft 112, at least one support 114, and/or at least one boat 116 may be disposed in the chamber 110, but is not limited thereto.

The drive shaft 112 and the support 114 may be disposed on a lower portion of the chamber 110. The support 114 may be disposed on the drive shaft 112. The boat 116 may be disposed on the support 114, and the support 114 may support the boat 116. The boat 116 may accommodate the plurality of substrates W disposed in a vertical direction, but is not limited thereto. Upper surfaces of the substrates W may be disposed to be oriented in the vertical direction (Z-direction). The drive shaft 112 may rotate the support 114, the boat 116, and the substrates W in a horizontal direction, such that the substrates W may be evenly heated in the heating process.

The substrate processing apparatus 100 may further include at least one discharge port 118 connected to the chamber 110. The discharge port 118 may be connected to a lower portion of the chamber 110, may discharge process gases and/or by-products in the chamber 110, and/or may adjust internal pressure of the chamber 110. For example, the discharge port 118 may be connected to at least one vacuum pump P, but is not limited thereto.

The plurality of antennas 120 may each be connected to one of the sidewalls of the chamber 110, and may transmit microwaves M1 and/or M2 to the substrates W in the chamber 110. For example, as illustrated in FIG. 2, the chamber 110 may include a first sidewall 110a, a second sidewall 110b, a third sidewall 110c, and a fourth sidewall 110d, but is not limited thereto. The first sidewall 110a may face the second sidewall 110b, and the third sidewall 110c may face the fourth sidewall 110d, etc. The antennas 120 may include one or more first antennas 120a and one or more second antennas 120b, disposed to face each other, but the example embodiments are not limited thereto. For example, the first antennas 120a and the second antennas 120b may be connected to the first sidewall 110a and the second sidewall 110b of the chamber 110, respectively, but the example embodiments are not limited thereto, and for example, a plurality of first antennas may be attached to the first sidewall 110a and a plurality of second antennas may be attached to the second sidewall 110b, etc. The first antennas 120a may be spaced apart from each other in the vertical direction, and the second antennas 120b may be spaced apart from each other in the vertical direction. According to some example embodiments, the first antenna 120a and the second antenna 120b may be connected to the first sidewall 110a and the second sidewall 110b, respectively, etc.

The windows 130 may be disposed on the sidewalls of the chamber 110, and may be in contact with the antennas 120, but the example embodiments are not limited thereto, and for example, there may be a gap between the antennas 120 and the windows 130, etc. For example, the windows 130 may be disposed on the first and second sidewalls 110a and 110b of the chamber 110, respectively, and may be in contact with corresponding windows 130. The microwaves M1 and M2 may be transmitted to the inside of the chamber 110 through the windows 130. The windows 130 may include a dielectric material, and the dielectric material may include quartz, ceramic, or the like. The antennas 120 may not be in direct contact with the sidewalls of the chamber 110, and may be in contact with the windows 130 including the dielectric material, thereby preventing and/or reducing deformation of physical properties such as phases of the microwave M1 and M2 due to internal impedance of the chamber 110. In addition, the antennas 120 having one open surface may be in contact with the windows 130 without being in direct contact with the chamber 110, thereby maintaining constant internal pressure of the chamber 110 and/or improving the internal pressure of the chamber 110. For example, the inside of the chamber 110 may be maintained in a vacuum state by the windows 130.

The first antenna 120a may be connected to corresponding ones, among the tuners 140, the circulators 150, the signal generators 160, and the rods 170. For example, the tuners 140, the circulators 150, the signal generators 160, and the rods 170 may include a first tuner 140a, a first circulator 150a, a first signal generator 160a, and a first rod 170a, respectively. The first antenna 120a may be connected to the first tuner 140a through a first waveguide L1. The first tuner 140a may be connected to the first circulator 150a through a second waveguide L2. The first circulator 150a may be connected to the first rod 170a and the first signal generator 160a through a third waveguide L3 and a fourth waveguide L4, respectively. The first antenna 120a may transmit or receive a microwave. For example, the first antenna 120a may transmit a microwave, generated by the first signal generator 160a, to the inside of the chamber 110. In addition, the first antenna 120a may receive a microwave from the inside of the chamber 110 and transmit the microwave to the first circulator 150a. For example, the first antenna 120a may receive a reflected wave, not absorbed in the chamber 110 or microwaves, transmitted from other antennas 120, and transmit the reflected wave or the microwaves to the first circulator 150a.

The first signal generator 160a may generate at least one microwave (e.g., at least one microwave signal, etc.). The frequency of the microwave may be configurable, e.g., approximately 2.45 GHZ, 5.8 GHz, and/or 28 GHZ, etc., but the example embodiments are not limited thereto. In at least one example embodiment, the microwave, generated by the first signal generator 160a, may have a variable frequency.

The microwave, generated by the first signal generator 160a, may be transmitted to the first circulator 150a, etc. The microwave, generated by the first signal generator 160a, may pass through the first circulator 150a, may be transmitted to the first tuner 140a through the second waveguide L2, and may be transmitted back to the first antenna 120a through the first waveguide L1. In addition, as described above, the microwave, received from the inside of the chamber 110 by the first antenna 120a, may be transmitted to the first circulator 150a. The first circulator 150a may transmit the microwave, received from the inside of the chamber 110, to the first rod 170a through the third waveguide L3.

The first rod 170a may remove the microwave received from the inside of the chamber 110 by the first antenna 120a. For example, coolant may be supplied to the first rod 170a, and absorbed heat may be discharged to the outside (e.g., to a destination external to the substrate processing apparatus, etc.). Accordingly, the first antenna 120a may reduce and/or prevent the first signal generator 160a from being damaged by the microwave received from the inside of the chamber 110. In at least one example embodiment, a detector for measuring the microwave, generated by the first signal generator 160a, and the microwave, received from the inside of the chamber 110 by the first antenna 120a, may be disposed between the first tuner 140a and the first circulator 150a. The detector may be a directional coupler, etc., but is not limited thereto.

The first tuner 140a may transmit the microwave, generated by the first signal generator 160a, through the second waveguide L2. The first tuner 140a may match the impedances between the first signal generator 160a and the chamber 110 to increase and/or improve the transmission efficiency of the microwaves. The first tuner 140a may include conductor plates that may be partially inserted into the first waveguide L1 and/or the second waveguide L2. The impedance between the first signal generator 160a and the chamber 110 may be adjusted by adjusting the number of the inserted conductor plates and/or adjusting a depth at which the conductor plates are inserted.

The microwave, generated by the first signal generator 160a, may be transmitted to the chamber 110 through the first tuner 140a and the first antenna 120a. The microwave, transmitted to the chamber 110 through the first antenna 120a, may be referred to as a first microwave M1. FIG. 1 illustrates only that an uppermost first antenna 120a, among the first antennas 120a, is connected to the first signal generator 160a, but the remaining first antennas 120a may also have a structure the same as, or similar to, that of the uppermost first antenna 120a. For example, the remaining first antennas 120a may also be connected to corresponding first signal generators 160a, respectively, but the example embodiments are not limited thereto.

The second antenna 120b may be connected to corresponding ones, among the tuners 140, the circulators 150, the signal generators 160, and/or the rods 170, etc. For example, the tuners 140, the circulators 150, the signal generators 160, and/or the rods 170 may include a second tuner 140b, a second circulator 150b, a second signal generator 160b, and a second rod 170b, respectively, but the example embodiments are not limited thereto. The second antenna 120b, the second tuner 140b, the second circulator 150b, the second signal generator 160b, and the second rod 170b may have structures the same as, or similar to, those of the first antenna 120b, the first tuner 140a, the first circulator 150a, the first signal generator 160a, and the first rod 170a, respectively, but are not limited thereto.

The second antenna 120b may be connected to the second tuner 140b through a fifth waveguide L5. The second tuner 140b may be connected to the second circulator 150b through a sixth waveguide L6. The second circulator 150b may be connected to the second rod 170b and the second signal generator 160b through a seventh waveguide L7 and an eighth waveguide L8, respectively. The second antenna 120b may transmit and/or receive a microwave. For example, the second antenna 120b may transmit a microwave, generated by the second signal generator 160b, to the inside of the chamber 110. In addition, the second antenna 120b may receive a microwave from the inside of the chamber 110 and/or transmit the microwave to the second circulator 150b. For example, the second antenna 120b may receive a reflected wave, not absorbed in the chamber 110, and/or microwaves transmitted from other antennas 120, and may transmit the reflected wave or the microwaves to the second circulator 150b.

The second signal generator 160b may generate at least one microwave (e.g., microwave signal, etc.), for example, at least one microwave having a frequency that is the same as that of the first signal generator 160a, but the example embodiments are not limited thereto. In at least one example embodiment, the microwave, generated by the second signal generator 160b, may have a variable frequency.

FIG. 1 illustrates only that an uppermost second antenna 120b of the second antennas 120b is connected to a second signal generator 160b, but the remaining second antennas 120b may also have a structure that is the same as, or similar to, that of the uppermost second antenna 120b. For example, the remaining second antennas 120b may be connected to corresponding second signal generators 160b, respectively, but are not limited thereto.

The microwave, generated by the second signal generator 160b, may be transmitted to the chamber 110 through the second tuner 140b and the second antenna 120b, etc. The microwave, transmitted to the chamber 110 through the second antenna 120b, may be referred to as a second microwave M2. In at least one example embodiment, an orientation direction of the first antenna 120a may be different from an orientation direction of the second antenna 120b. For example, the first antenna 120a may be disposed on a level the same as that of the second antenna 120b, and may face the second antenna 120b. Here, the “orientation direction” may refer to a main traveling direction of the first and second microwaves M1 and M2 transmitted from the first and second antennas 120a and 120b. Here, the “level” may refer to a vertical distance from a lower surface of the chamber 110. Both the orientation direction of the first antenna 120a and the orientation direction of the second antenna 120b may be parallel to an upper surface of the substrate W, but the example embodiments are not limited thereto.

The controller 180 (e.g., processing circuitry, processor, etc.) may control the first signal generator 160a and/or the second signal generator 160b, etc., but is not limited thereto. For example, the controller 180 may change the frequencies of the first and/or second microwaves M1 and M2 (e.g., microwave signals, etc.), generated by the first signal generator 160a and the second signal generator 160b, over time. The controller 180 may also synchronize phases of the first and second microwaves M1 and M2 with each other. Accordingly, the first and second microwaves M1 and M2 having the synchronized phases may form a standing wave in the chamber 110. According to some example embodiments, the controller 180, the first signal generator 160a, and/or the second signal generator 160b, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

In at least one example embodiment, the substrate processing apparatus 100 may further include one or more sensors 125. For example, the sensors 125 may include a first sensor 125a and/or a second sensor 125b, etc., but is not limited thereto. For example, the first sensor 125a may be disposed between the first antenna 120a and the first tuner 140a, for example, in the first waveguide L1. The first sensor 125a may be connected to the first antenna 120a, and may measure an intensity and/or a phase of the first microwave M1 transmitted to the first antenna 120a, etc. An intensity value and/or a phase value measured by the first sensor 125a may be transmitted to the controller 180.

The second sensor 125b may be disposed between the second antenna 120b and the second tuner 140b, and may be, for example, disposed in the fifth waveguide L5. The second sensor 125b may be connected to the second antenna 120b, and may measure an intensity and/or a phase of the second microwave M2 transmitted to the second antenna 120b. An intensity value and/or a phase value measured by the second sensor 125b may be transmitted to the controller 180. The controller 180 may control, based on the values measured by the first sensor 125a and/or the second sensor 125b, the first signal generator 160a and/or the second signal generator 160b, such that the phases of the first and second microwaves M1 and M2 may be synchronized with each other, but the example embodiments are not limited thereto.

When a microwave is transmitted into a closed space, such as the interior of the chamber 110, a travelling wave travelling to the inside of the chamber 110 and a reflected wave reflected from a wall surface of the chamber 110 may interfere with each other, such that an intensity of the microwave may locally vary. In addition, as substrates are heated by the microwave, the temperature of the substrates and/or the temperature of the internal components of the chamber 110 may change, and accordingly, internal impedance of the chamber 110 may change. Therefore, when a microwave is transmitted in a closed space, it may be difficult to predict a change in the internal impedance of the closed space, e.g., the chamber 110, and it may be difficult to generate a microwave with sufficiently high power to sufficiently heat the substrates because the heating efficiency may be lowered.

However, according to some example embodiments of the inventive concepts, the chamber 110 may not be a closed space. For example, the first microwave M1, transmitted from the first antenna 120a to the inside (e.g., interior) of the chamber 110, may heat the substrates W, and may travel to the second antenna 120b and may be received by the second antenna 120b. The first microwave M1 received by the second antenna 120b, may be removed by the second rod 170b. The second microwave M2, transmitted from the second antenna 120b to the inside (e.g., interior) of the chamber 110, may heat the substrates W, and may travel to the first antenna 120a and may be received by the first antenna 120a. The second microwave M2 received by the first antenna 120a, may be removed by the first rod 170a. Accordingly, the first and second microwaves M1 and M2 may be received by the second antenna 120b and the first antenna 120a, respectively, thereby preventing and/or reducing the reflection of the first and second microwaves M1 and M2 from at least one wall surface of the chamber 110. Accordingly, interference of the first and second microwaves M1 and M2 by at least one reflected wave may be prevented and/or reduced, and the intensities of the first and second microwaves M1 and M2 in the chamber 110 may be relatively adjusted within a predictable and/or desired range. Accordingly, efficiency of heating the substrates W may be increased, and a heating process may be performed by generating the first and second microwaves M1 and M2 with relatively low intensity. In addition, the intensities of the first and second microwaves M1 and M2 in the chamber 110 may not be unpredictably deformed, relatively, such that the substrates W may be evenly heated over the entire upper surfaces thereof.

Hereinafter, a method of heating a substrate according to at least one example embodiment of the inventive concepts will be described. In at least one example embodiment, the substrates W may be heated by forming at least one standing wave in the chamber 110. For example, the first and second antennas 120a and 120b may transmit the first and second microwaves M1 and M2 to the inside (e.g., interior) of the chamber 110, respectively. The controller 180 may control the first and second signal generators 160a and 160b, such that the phases of the first and second microwaves M1 and M2 may be synchronized with each other, but the example embodiments are not limited thereto. For example, the controller 180 may control the first and second signal generators 160a and 160b, based on the values of the first and second antennas 120a and 120b measured by the first and second sensors 125a and 125b. The first and second microwaves M1 and M2 having the synchronized phases may form a standing wave in the chamber 110. In at least one example embodiment, the frequencies of the first and second microwaves M1 and M2 may be deformed by the controller 180, and the boat 116 loaded with the substrates W may rotate in the horizontal direction by the drive shaft 112. Accordingly, the upper surfaces of the substrates W may be evenly heated.

In at least one example embodiment, a standing wave may not be formed in the chamber 110. For example, one of the first and second signal generators 160a and 160b may not operate. One of the first and second microwaves M1 and M2, generated by one of the first and second antennas 120a and 120b, may travel to the inside of the chamber 110 to heat the substrates W, and may be received by the other one of the first and second antennas 120a and 120b and removed. In this case, one of the first and second microwaves M1 and M2 may not form a standing wave in the chamber 110, and may heat the substrates W as a traveling wave passing through the chamber 110. One of the first and second microwaves M1 and M2 may be received by the other one of the first and second antennas 120a and 120b and removed, thereby preventing and/or reducing formation of a reflected wave due to reflection from the inside of the chamber 110. Accordingly, interference of one of the first and second microwaves M1 and M2 with the reflected wave may be prevented and/or reduced, and the efficiency of heating the substrates W may be increased.

FIG. 3 is a perspective view of an antenna according to at least one example embodiment.

Referring further to FIG. 3, the antennas 120 according to some example embodiments of the inventive concepts may be directional antennas. Widths W1 and W2 of the first antenna 120a may vary in an X-direction. For example, a horizontal width W1 and a vertical width W2 of the first antenna 120a may increase as a distance from the chamber 110 decreases, but the example embodiments are not limited thereto. The first antenna 120a may extend in the X-direction, and may increase as the distance from the chamber 110 decreases, such that the first antenna 120a may have an orientation direction, parallel to an upper surface of the substrate W (parallel to the X-direction), but is not limited thereto.

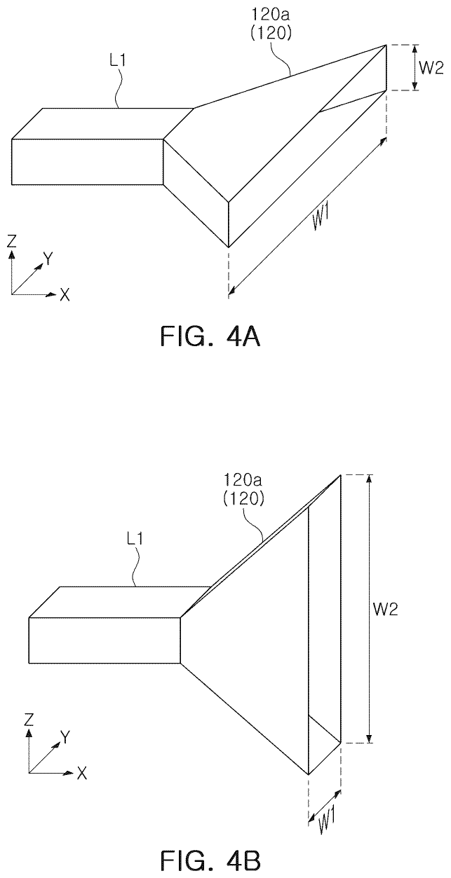

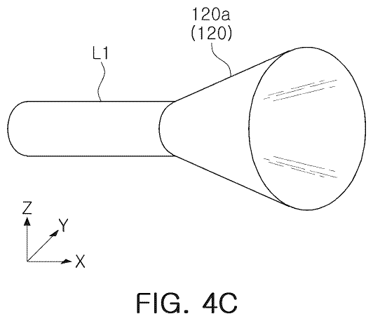

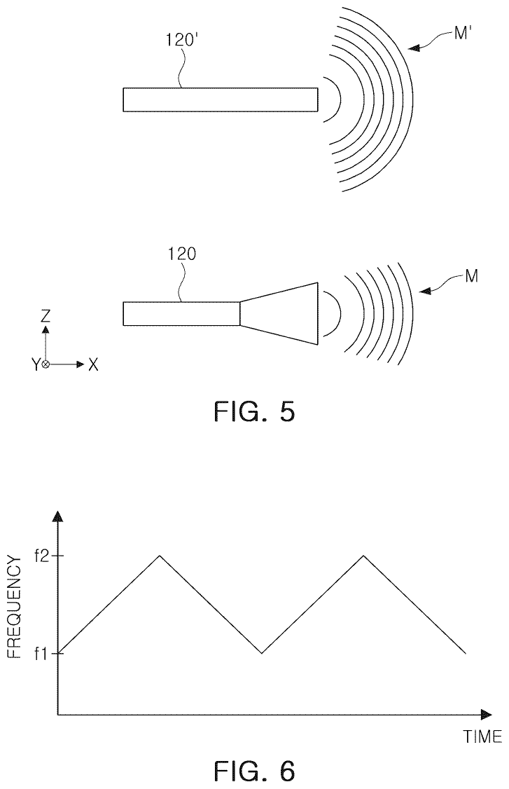

FIGS. 4A to 4C are perspective views of an antenna according to at least one example embodiment.

Referring to FIG. 4A, the horizontal width W1 of the first antenna 120a may be greater than the vertical width W2 of the first antenna 120a, but the example embodiments are not limited thereto. Referring to FIG. 4B, the vertical width W2 of the first antenna 120a may be greater than the horizontal width W1 of the first antenna 120a, but is not limited thereto. Referring to FIG. 4C, the first antenna 120a may have a conical shape, and the first antenna 120a may have a circular cross-section, but is not limited thereto. In each example embodiment, the second antenna 120b may have a shape that is the same as that of the first antenna 120a disposed to face the second antenna 120a, but the example embodiments are not limited thereto.

FIG. 5 is a schematic diagram illustrating a microwave being transmitted from an antenna according to a comparative example embodiment and at least one example embodiment.

Referring to FIG. 5, a microwave M′ in a comparative example embodiment may be more widely propagated than a microwave M in the at least one example embodiment of the inventive concepts. For example, in the comparative example embodiment, the microwave M′ may radially travel from a cross-section of an antenna 120′. However, the microwave M, transmitted from the antenna 120 according to some example embodiments of the inventive concepts, may be concentrated and propagated in an X-direction, a main traveling direction. The antenna 120 according to some example embodiments of the inventive concepts may be a directional antenna, such that efficiency of transmitting the microwave M may be increased. In addition, the antenna 120 may be a directional antenna, such that interference with a reflected wave reflected from an inner wall of the chamber 110 may be reduced, thereby preventing and/or reducing unpredictable deformation of the microwave M due to interference with the reflected wave. In addition, as described above, the microwave M traveling in an orientation direction (e.g., X-direction) may be received by a corresponding antenna 120, thereby further reducing the reflected wave.

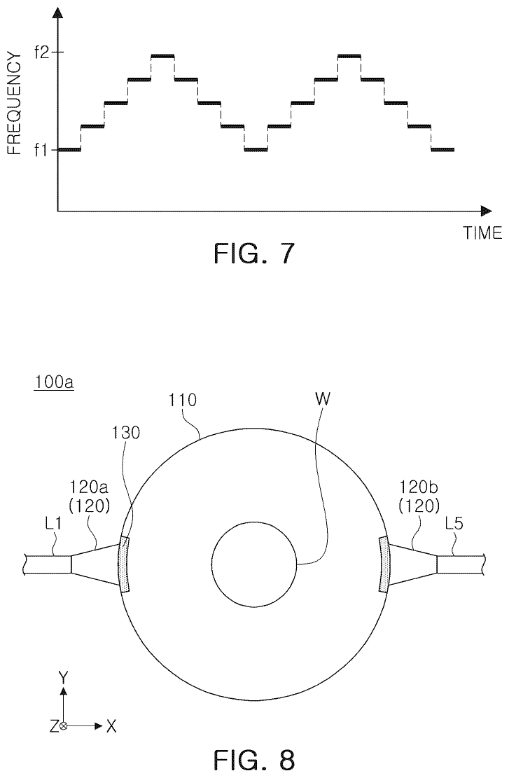

FIGS. 6 and 7 illustrate a frequency change over time of a microwave according to some example embodiments.

Referring to FIG. 6, frequencies of the microwaves M1 and M2 may change over time. For example, the controller 180 may change a frequency of at least one of the microwaves M1 and M2 by controlling at least one of the first signal generator 160a and/or the second signal generator 160b. At least one of the microwaves M1 and M2 may increase and/or decrease in a desired and/or predetermined cycle between the first frequency f1 and the second frequency f2, greater than the first frequency f1. A frequency change rate and cycle over time are examples, and the example embodiments of the inventive concepts are not limited thereto.

Referring to FIG. 7, frequencies of the microwaves M1 and/or M2 may change over time. For example, a frequency of at least one of the microwaves M1 and/or M2 may have a discrete value maintained between the first frequency f1 and the second frequency f2 for a desired predetermined period of time. For example, a frequency of at least one of the microwaves M1 and M2 may increase and decrease in a stepwise manner, but is not limited thereto.

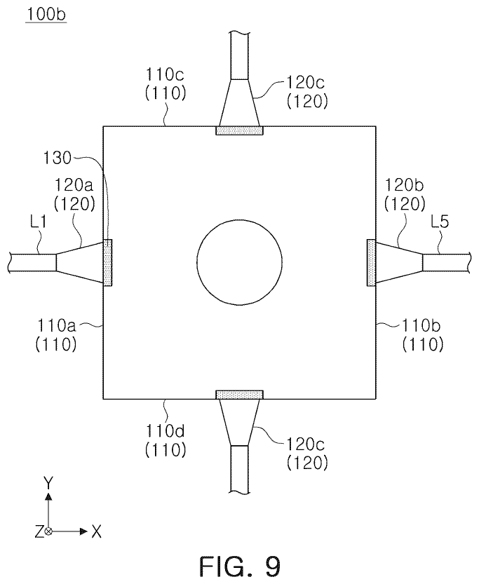

FIGS. 8 and 9 are plan views of a substrate processing apparatus according to some example embodiments.

Referring to FIG. 8, a substrate processing apparatus 100a may include a chamber 110 to which a first antenna 120a and a second antenna 120b are connected, but the example embodiments are not limited thereto. In at least one example embodiment, the chamber 110 may have a cylindrical shape, but is not limited thereto, and for example, may have other geometric shapes having opposing sides, such as a hexagonal shape, etc. For example, in plan view, the chamber 110 may have a circular shape, etc. The first antenna 120a and the second antenna 120b may be disposed to face each other with at least one substrate W interposed therebetween.

Referring to FIG. 9, a substrate processing apparatus 100b may include a plurality of antennas 120 connected to a chamber 110. In at least one example embodiment, the antennas 120 may include a first antenna 120a, a second antenna 120b, a third antenna 120c, and a fourth antenna 120d respectively connected to a first sidewall 110a, a second sidewall 110b, a third sidewall 110c, and a fourth sidewall 110d of the chamber 110, etc. The first antenna 120a and the second antenna 120b may have structures the same as, or similar, to those of the antennas 120 described with reference to FIGS. 1 to 3, but are not limited thereto. The third antenna 120c and the fourth antenna 120d may have structures the same as, or similar to, those of the first antenna 120a and the second antenna 120b, but are not limited thereto. For example, the third antenna 120c and the fourth antenna 120d may be disposed to face each other with at least one substrate W interposed therebetween. A microwave transmitted from the third antenna 120c to the inside (e.g., interior) of the chamber 110 may pass through the substrate W and may be received by the fourth antenna 120d. A microwave transmitted from the fourth antenna 120d to the inside (e.g., interior) of the chamber 110 may pass through the substrate W and may be received by the third antenna 120c.

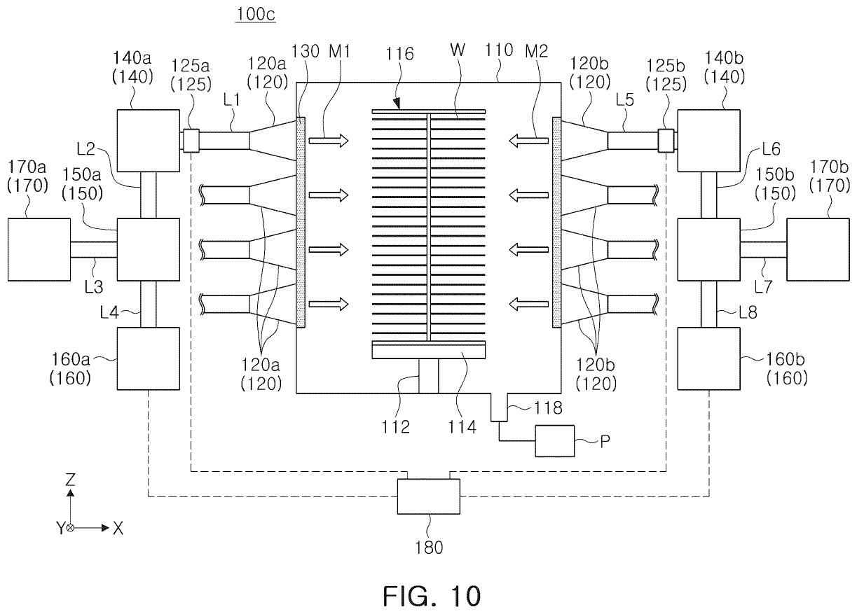

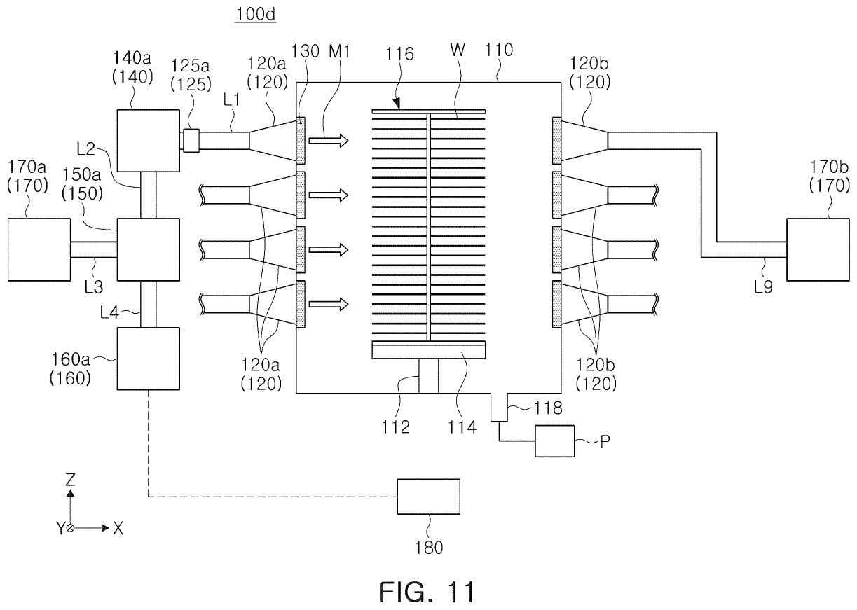

FIGS. 10 and 11 are cross-sectional views of a substrate processing apparatus according to some example embodiments.

Referring to FIG. 10, a substrate processing apparatus 100c may include at least one window 130 disposed on a sidewall of the chamber 110. In at least one example embodiment, the window 130 may extend in a vertical direction, and may be in contact with a plurality of antennas 120 spaced apart from each other in the vertical direction, but is not limited thereto.

Referring to FIG. 11, a substrate processing apparatus 100d may include at least one first antenna 120a and at least one second antenna 120b connected to a chamber 110, but is not limited thereto. Unlike the substrate processing apparatus 100 illustrated in FIG. 1, a second tuner 140b, a second circulator 150b, and/or a second signal generator 160b may be omitted. For example, a first microwave M1 may be transmitted only from the first antenna 120a, and the second antenna 120b may not transmit a microwave. The second antenna 120b may receive the first microwave M1, and the received first microwave M1 may be transmitted to the second rod 170b and removed by the second rod 170bc, etc.

In this case, the first microwave M1 may not form a standing wave in the chamber 110, and may heat substrates W as a traveling wave passing through the chamber 110. The first microwave M1 may be received by the second antenna 120b and removed, thereby preventing and/or reducing formation of a reflected wave due to reflection from the inside of the chamber 110. Accordingly, interference of the first microwave M1 with the reflected wave may be prevented and/or reduced, and the efficiency of heating the substrates W may be increased.

According to one or more example embodiments of the inventive concepts, directional antennas may be disposed on sidewalls of a chamber to face each other, thereby decreasing and/or preventing microwaves transmitted from the antennas from forming reflected waves in the chamber, and/or reducing the reflected waves formed by the microwaves. Accordingly, a substrate placed inside the chamber may be more evenly heated and/or have improved heating.

While some example embodiments have been shown and described above, it will be apparent to those of ordinary skill in the art that modifications and/or variations could be made without departing from the scope of the example embodiments of the inventive concepts as defined by the appended claims.

What is claimed is:

1. A substrate processing apparatus comprising:
a chamber;
a boat inside the chamber, the boat configured to support one or more semiconductor substrates;
first and second antennas connected to sidewalls of the chamber, the first and second antennas facing each other;
a first signal generator configured to transmit a first microwave signal to the first antenna;
a first rod connected to the first antenna, the first rod configured to remove a second microwave signal received by the first antenna;
a second rod connected to the second antenna, the second rod configured to remove the first microwave signal which was received by the second antenna; and
processing circuitry configured to control at least the first signal generator.

2. The substrate processing apparatus of claim 1, wherein
the second antenna is configured to receive the first microwave signal transmitted by the first antenna.

3. The substrate processing apparatus of claim 1, wherein a width of the first antenna increases as a distance to the chamber decreases.

4. The substrate processing apparatus of claim 1, wherein an orientation direction of the first antenna is parallel to one or more upper surfaces of the one or more semiconductor substrates.

5. The substrate processing apparatus of claim 1, further comprising:
a first circulator between the first antenna and the first signal generator,
wherein the first circulator is configured to transmit the second microwave signal received by the first antenna to the first rod.

6. The substrate processing apparatus of claim 5, further comprising:
a first sensor between the first antenna and the first circulator, the first sensor configured to,
measure a first phase value of the first microwave signal, and
transmit the first phase value to the processing circuitry.

7. The substrate processing apparatus of claim 6, wherein the processing circuitry is further configured to:
control a phase of the first microwave signal based on the first phase value.

8. The substrate processing apparatus of claim 1, wherein the processing circuitry is further configured to:
change a frequency of the first microwave signal over time.

9. The substrate processing apparatus of claim 1, further comprising:
a window on the sidewall of the chamber, the window in contact with the first antenna; and
the first antenna is further configured to transmit the first microwave signal to an interior of the chamber through the window.

10. The substrate processing apparatus of claim 9, further comprising:
a third antenna spaced apart from the first antenna in a vertical direction,
wherein at least a portion of the window is in contact with the third antenna.

11. The substrate processing apparatus of claim 1, further comprising:
a second signal generator configured to transmit the second microwave signal to the second antenna; and
the second antenna is further configured to receive the second microwave signal from the second signal generator and transmit the received second microwave signal to the one or more semiconductor substrates.

12. The substrate processing apparatus of claim 11, further comprising:
a second circulator between the second antenna and the second signal generator,
wherein the second circulator is configured to transmit the first microwave signal received by the second antenna to the second rod.

13. The substrate processing apparatus of claim 12, further comprising:
a second sensor between the second antenna and the second circulator, the second sensor configured to,
measure a second phase value of the second microwave signal, and
transmit the second phase value to the processing circuitry.

14. The substrate processing apparatus of claim 13, wherein the processing circuitry is further configured to:
control a phase of the second microwave signal based on the second phase value.

15. A substrate processing apparatus comprising:
a chamber;
a boat inside the chamber, the boat configured to support one or more semiconductor substrates;
first and second antennas connected to sidewalls of the chamber with the one or more semiconductor substrates interposed therebetween;
a first signal generator configured to transmit a first microwave signal to the first antenna;
a first rod connected to the first antenna, the first rod configured to remove a second microwave signal received by the first antenna;
a second rod connected to the second antenna, the second rod configured to remove the first microwave signal received by the second antenna; and
processing circuitry configured to control at least the first signal generator,
wherein the one or more semiconductor substrates are heated by the first microwave signal.

16. The substrate processing apparatus of claim 15, wherein the first antenna and the second antenna face each other.

17. The substrate processing apparatus of claim 15, further comprising:
a second signal generator configured to transmit the second microwave signal to the second antenna;
wherein the processing circuitry is further configured to control the second signal generator, and
the one or more semiconductor substrates are heated by the second microwave signal.

18. The substrate processing apparatus of claim 17, wherein
the first antenna is further configured to receive the second microwave signal and transmit the received second microwave signal to the first rod.

19. The substrate processing apparatus of claim 17, wherein the processing circuitry is further configured to:
control the first signal generator and the second signal generator such that a phase of the first microwave signal is synchronized with a phase of the second microwave signal.

20. A substrate processing apparatus comprising:
a chamber;
a boat inside the chamber, the boat configured to support one or more semiconductor substrates;
a support configured to support the boat;
a drive shaft configured to rotate the support and the boat in a horizontal direction;
first and second antennas connected to sidewalls of the chamber, the first and second antennas facing each other;
a first signal generator configured to transmit a first microwave signal to the first antenna;
a first rod connected to the first antenna, the first rod configured to remove a second microwave signal received by the first antenna;
a second rod connected to the second antenna, the second rod configured to remove the first microwave signal received by the second antenna; and
processing circuitry configured to control at least the first signal generator,
wherein widths of the first antenna and the second antenna increase as distances between the first antenna and the second antenna and the chamber respectively decreases.
